(19) United States
(12) Patent Application Publication
(10) Pub. No.: US 2024/0361815 A1
(43) Pub. Date: Oct. 31, 2024

(54) Thermal Conduction System for use with a Portable Information Handling System

(71) Applicant: Dell Products L.P., Round Rock, TX (US)

(72) Inventors: Luke Adams, College Station, TX (US); Elochukwu Ugwu, Pflugerville, TX (US); Qinghong He, Austin, TX (US)

(73) Assignee: Dell Products L.P., Round Rock, TX (US)

(21) Appl. No.: 18/139,423

(22) Filed: Apr. 26, 2023

(51) Int. Cl. G06F 1/20; G06F 1/16; H05K 7/20

(52) U.S. Cl. CPC G06F 1/203; G06F 1/1632; H05K 7/20145; H05K 7/20336; H05K 7/20472; G06F 2200/201

(57) ABSTRACT

A main housing portion of a portable information handing system. The main housing portion includes: a top cover portion; a bottom cover portion defining a plurality of bottom cover portion apertures and, a thermal cooling device, the thermal cooling device comprising a thermal interface material component, the thermal cooling device comprising a thermal interface material component, the thermal interface material component being configured to contact a docking station thermal component of a docking station.

### BACKGROUND OF THE INVENTION

### Field of the Invention

The present invention relates to information handling systems. More specifically, embodiments of the invention relate to a thermal conduction system for use with a portable information handling system.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

### SUMMARY OF THE INVENTION

In one embodiment the invention relates to a main housing portion of a portable information handing system, comprising: a top cover portion; a bottom cover portion the bottom cover portion defining a plurality of bottom cover portion apertures; and, a thermal cooling device, the thermal cooling device comprising a thermal interface material component, the thermal interface material component being configured to contact a docking station thermal component of a docking station.

In another embodiment the invention relates to an information handling system comprising: a processor; a data bus coupled to the processor; and an information handling system chassis housing, the housing comprising a base chassis, the base chassis housing the processor, the base chassis comprising a top cover portion; a bottom cover portion defining a plurality of bottom cover portion apertures; and, a thermal cooling device, the thermal cooling device comprising a thermal interface material component, the thermal interface material component being configured to contact a docking station thermal component of a docking station.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of an example portable information handling system.

FIG. 3 shows a blown-up view of a portable information handling system.

FIG. 4 shows a cross sectional block diagram of a thermal dock interface system according to an embodiment of the disclosure.

FIG. 5 shows a bottom view of an information handling system with a thermal dock interface according to an embodiment of the disclosure.

FIG. 6 shows a perspective view of a docking solution with a thermal dock interface according to an embodiment of the disclosure.

FIG. 7 shows a perspective view of an information handling system and docking solution with a thermal dock interface system according to an embodiment of the disclosure.

### DETAILED DESCRIPTION

Various aspects of the present disclosure include an appreciation that portable information handling systems with higher performance requirements often present thermal challenges. Various aspects of the present disclosure include an appreciation that known cooling solutions for portable information handling system often include a thermal interface with high heat producing components such as a central processing unit (CPU) and/or a graphics processing unit (GPU), connected to heat pipes which are thermally coupled to a radiator where the heat is dissipated. Such a thermal solution can be heavily constrained by system size and acoustic requirements.

Various aspects of the present disclosure include an appreciation that portable information handling systems often have to compromise performance to achieve a desired weight or size that are important mobility considerations. Various aspects of the present disclosure include an appreciation that portable information handling systems that with on desk usage scenarios mobility is often less important to the user. With such a usage scenario a docking solution can be introduced to provide the portable information handling system with better performance. In such a usage scenario, the docking solution functions as a peripheral device capable of supplemental cooling without affecting the mobility of the portable information handling system when it is needed.

Various aspects of the present disclosure include an appreciation that known docking solutions are designed to either push or pull more airflow through the portable information handling system with external fans. Various aspects of the present disclosure include an appreciation that some known docking solutions are designed with a combination of pushing and pulling the same time. These known docking solutions may be generally referred to as convection docking solutions as they improve thermal capacity by providing more convection cooling.

Various aspects of the present disclosure include an appreciation that known docking solutions a constraint for this type of thermal solution is that the system airflow impedance exhibits roughly a square relationship to airflow (e.g., 4× of pressure is needed to achieve 2× airflow through the portable information handling system). Due to a relatively small form factor of portable information handling systems, impedance to airflow is usually high. Accordingly, fundamental fluid physics of the impedance to airflow can limit the effectiveness of an external cooling dock, resulting in only a diminishing return after a certain point, particularly when the fan noise is taken into consideration.

Accordingly, a thermal solution is disclosed which provides thermal conduction cooling by providing a mechanical and thermal interface with an internal thermal solution of the portable information handling system. Such a thermal conduction cooling solution provides a user with more thermal headroom for their components when docked and a smaller more portable device when undocked without the risk of exposing the user to hot components. A thermal conduction solution uses thermal conduction to draw heat from the portable information handling system. Various aspects of the present disclosure include an appreciation that a challenge with providing a thermal conduction solution is that for safety and user experience reasons, it is desirable to not expose hot surfaces to the user.

In various aspects of the disclosure, a thermal solution is provided which includes one or more design features. In various embodiments, the thermal conduction solution includes apertures in the bottom of the portable information handling system. In certain embodiments, the apertures are positioned below a CPU/GPU cold plate. In certain embodiments, the apertures are defined by a D-cover of the portable information handling system. In certain embodiments, the CPU/GPU cold plate includes a thin thermal pad on the bottom in the small hole area. In certain embodiments, the thermal solution includes a docking station with thermally conductive pins protruding from a surface of the docking station. In certain embodiments, the thermally conductive pins are formed from copper. When the portable information handling system is docked to the docking station, the thermally conductive pins mate with apertures on the bottom of the portable information handling system and contact the thermal pad, thus providing a conduction path from the thermal pad to the docking station.

Such a thermal solution provides efficient thermal conduction to draw heat away from the portable information handling system. With such a thermal solution, the thermal dock airflow path and the system airflow path are independent (i.e., not shared) so thermal dock can have much lower flow impedance to achieve a greater total (system+dock) airflow. With such a thermal solution the apertures eliminate the touch temperature problem when the information handling system is undocked. Such a thermal solution can be used on liquid cooled docks which traditionally require liquid inside the system making them not practical in most portable information handling systems. Such a thermal solution can provide in excess of 100 W of additional cooling for the portable information handling systems.

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

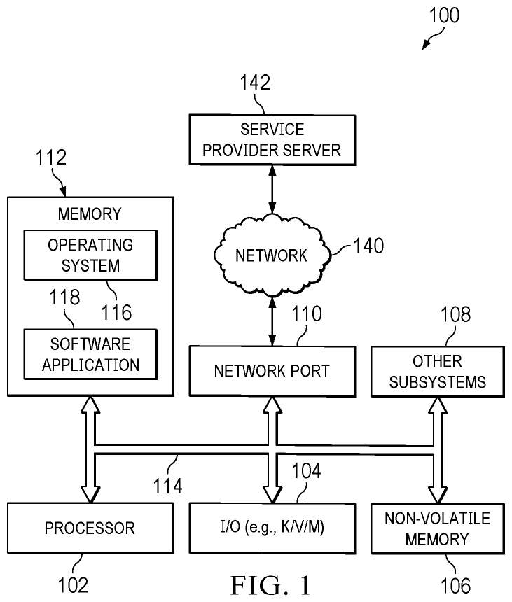

FIG. 1 is a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, a touchpad or touchscreen, and associated controllers, a hard drive or disk storage 106, and various other subsystems 108. In various embodiments, the information handling system 100 also includes network port 110 operable to connect to a network 140, which is likewise accessible by a service provider server 142. The information handling system 100 likewise includes system memory 112, which is interconnected to the foregoing via one or more buses 114. System memory 112 further comprises operating system (OS) 116 and in various embodiments may also comprise at least one software application 118. In one embodiment, the information handling system 100 is able to download the software application from the service provider server 142. In another embodiment, the software application 118 is provided as a service from the service provider server 142. In certain embodiments, the information handling system 100 also includes a thermal dock interface 150.

The thermal dock interface 150 interacts with a thermal component of a docking station to provide thermal conduction cooling via a mechanical and thermal interface between the thermal dock interface 150 and the thermal component. The thermal dock interface 150 and the thermal component of the docking station provide a thermal conduction cooling system. Such a thermal conduction cooling system provides a user with more thermal headroom for their components when docked and a smaller more portable device when undocked without the risk of exposing the user to hot components. A thermal conduction solution uses thermal conduction to draw heat from the portable information handling system.

The thermal conduction system includes one or more design features. In various embodiments, the thermal conduction system includes apertures in the bottom of the information handling system. In certain embodiments, the apertures are positioned below a CPU/GPU cold plate. In certain embodiments, the apertures are defined by a D-cover of the portable information handling system. In certain embodiments, the CPU/GPU cold plate includes a thin thermal pad on the bottom in the small hole area. In certain embodiments, the thermal conduction system includes a docking station with thermally conductive pins protruding from a surface of the docking station. In certain embodiments, the thermally conductive pins are formed from copper. When the information handling system is docked to the docking station, the thermally conductive pins mate with the apertures on the bottom of the portable information handling system and contact the thermal pad, thus providing a thermal conduction path from the thermal pad to the docking station.

Such a thermal conduction system provides efficient thermal conduction to draw heat away from the portable information handling system. With such a thermal conduction system, thermal dock airflow and system airflow paths are independent (i.e., not shared) so airflow within the thermal dock can have much lower flow impedance to achieve a greater total (system+dock) airflow. With such a thermal conduction system, the apertures eliminate the touch temperature problem when the information handling system is undocked. Such a thermal conduction system can be used on liquid cooled docks which traditionally require liquid inside the system making them not practical in most portable information handling systems. Such a thermal system can provide in excess of 100 W of additional cooling for the portable information handling systems.

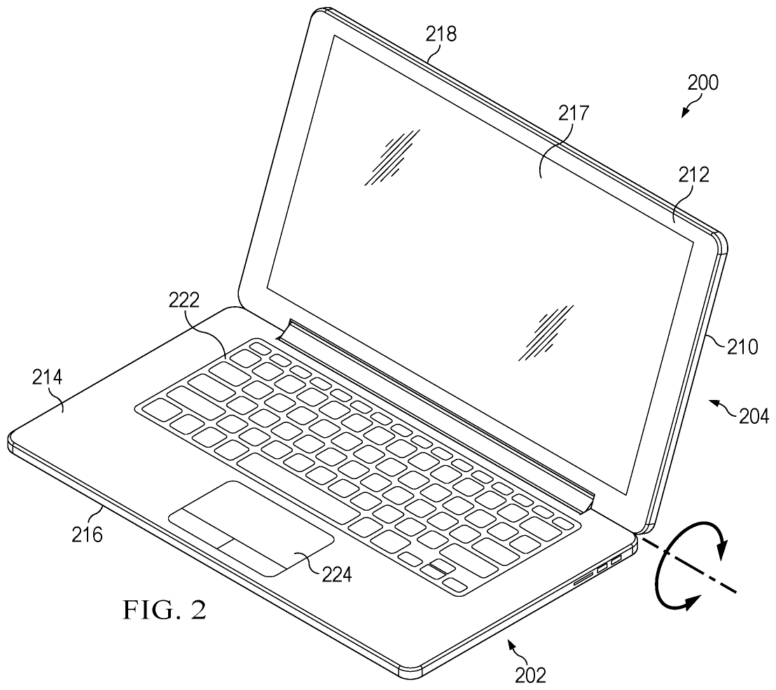

FIG. 2 shows a perspective view of an example portable information handling system chassis 200 such as a tablet type portable information handling system, a laptop type portable information handling system, or any other mobile information handling system. It will be appreciated that some or all of the components of the information handling system 100 may be included within information handling system chassis 200. The portable information handling system 200 chassis includes a base chassis 202 and a display chassis 204 shown in an open configuration. It will be appreciated that a closed configuration would have the display chassis 204 fully closed onto the base chassis 202.

The base chassis 202 or the display chassis 204 of the information handling system 200 may comprise an outer metal case or shell. The information handling system 200 may include a plurality of chassis portions. In various embodiments, the information handling system 200 may include some or all of an A-Cover 210, a B-Cover 212, a C-cover 214 and a D-Cover 216. In various embodiments, the A-Cover 210 and the B-Cover 212 provide the display chassis 204. In various embodiments, the C-Cover 214 and the D-Cover 216 provide the base chassis 202.

In various embodiments, the A-cover 210 encloses a portion of the display chassis 204 of the information handling system 200. In various embodiments, the B-cover 212 encloses another portion of the display chassis 204 of the information handling system 200. In various embodiments, the B-Cover may include a display screen 217 and a bezel 218 around the display screen.

In various embodiments, the C-cover 214 encloses a portion of the base chassis 202 of the information handling system 200. In various embodiments, the C-cover 214 may include, for example, a keyboard 222, a trackpad 224, or other input/output (I/O) device. In various embodiments, certain components of the information handling system such as a mother board are mounted within the C-Cover 214. In various embodiments, the D-cover 216 encloses another portion of the base chassis 202 of the information handling system 200.

When placed in the closed configuration, the A-cover 202 forms a top outer protective shell, or a portion of a lid, for the information handling system 200, while the D-cover 204 forms a bottom outer protective shell, or a portion of a base, for the information handling system. When in the fully closed configuration, the A-cover 202 and the D-cover 204 would be substantially parallel to one another.

In some embodiments, both the A-cover 202 and the D-cover 204 may be comprised entirely of metal. In some embodiments, the A-cover 202 and D-cover 204 may include both metallic and plastic components. For example, plastic components that are radio-frequency (RF) transparent may be used to form a portion of the C-cover 208.

In various embodiments, the A-cover 202 may be movably connected to a back edge of the D-cover 204 via one or more hinges. In this configuration, the hinges allow the A-cover 202 to rotate from and to the D-cover 204 allowing for multiple orientations of the information handling system 200. In various embodiments, the information handling system may include a sensor to detect the orientation of the information handling system and activate or deactivate any number of antenna systems based on the occurrence of any specific orientation. In some embodiments, the information handling system may be a laptop with limited rotation of the A-cover 204 with regard to the D-cover 204, for example up to 180° rotation arc. In other embodiments the information handling system 200 may be a convertible information handling system with full rotation to a tablet configuration.

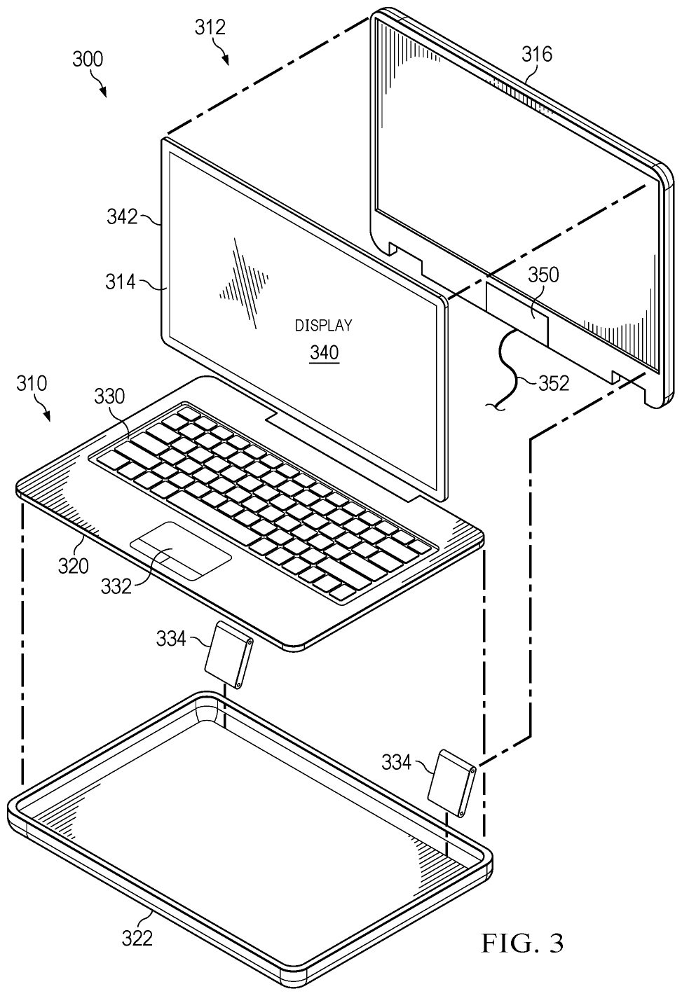

FIG. 3 shows a blown-up view of a portable information handling system 300 having rotationally-coupled housing portions. In the example embodiment, a main housing portion 310 (which corresponds to a base chassis 202) rotationally couples to a lid housing portion 312 (which corresponds to a display chassis 204) to support various configurations to interact with an end user. Main housing portion 310 may hold one or more components of the portable information handling system, including but not limited to processor 102, system bus 114, memory subsystem 112, I/O subsystem 104 and network interface 110 discussed with respect to FIG. 1. Main housing portion 310 includes a top cover portion 320 (which includes the C-Cover 214) and a bottom cover portion 322 (which includes the D-Cover 216). Lid housing portion 312 includes a display cover portion 314 (which includes the B-Cover 210) and a rear display cover portion 316 (which includes the A-Cover 212). The top cover portion 320 may include an integrated keyboard 330 or other I/O devices, such as a trackpad 332 or microphone (not shown). In various embodiments, the keyboard 330 may be mounted to the top of the C-Cover of the main housing portion 310. In various embodiments, the keyboard 330 may be mounted to the underside of the C-Cover of the main housing portion 310.

Lid housing portion 312 is rotationally coupled to main housing portion 310 via at least one hinge assembly 334. Lid housing portion 212 includes display 340 that visually presents information to the user as well as a bezel 342. Display 340 may be a touch panel with circuitry enabling touch functionality in conjunction with a display. In some embodiments, display 340 may be an “infinity edge” or “narrow bezel” display that approaches one or more the edges of lid housing portion 212 such that bezel may be narrow in size (e. g., less than 10 millimeters) on the edges. For example, display 340 is an infinity display with narrow bezels on the top and sides of lid housing portion 212 in the embodiment shown in FIG. 3. In certain embodiments, the side bezel is less than 4 mm (+/−10%) and the top bezel is less than 6 mm (+/−10%).

Lid housing portion 212 may also include timing controller (TCON) 350. Hinge assembly 330 may include cable 352 for communicably coupling one or more components within main housing portion 310 to one or more components within lid housing portion 312. For example, cable 352 may provide communication of graphics information from an I/O subsystem to TCON 350 for generation of visual images for display on display 340. Although a single cable 352 is shown, portable information handling system 300 may include one or more additional cables 352 for communicating components disposed in main housing portion 310 and lid housing portion 312. Placement of cable 352 may be selected based on design considerations, materials or manufacturing cost, material reliability, antenna placement, as well as any other considerations.

Hinge assembly 334 allows main housing portion 310 and lid housing portion 312 to rotate between a plurality of positions. For example, when portable information handling system 300 is not in use, lid housing portion 312 may be closed over the top of main portion 310 such that display 340 and keyboard 330 are protected from unintended use or damage. Rotation of lid housing portion 312 by approximately 90 degrees from main housing portion 310 brings display 340 in a raised “clamshell” position relative to keyboard 330 so that an end user can make inputs to keyboard 330 or touch panel portion of display 340 while viewing display 340. In some embodiments, clamshell position may represent lid housing portion 212 open between approximately 1 and 180 degrees from main housing portion 310. Rotation of lid housing portion 312 between approximately 180 and 359 degrees from main housing portion 310 may place portable information handling system 300 in “tablet stand” and/or “tent” positions. In tablet stand and tent positions, the user may make inputs via touch panel portion of display 340 while viewing display 340. A full 360 degree rotation of main housing portion 310 relative to lid housing portion 312 provides a tablet configuration having display 340 exposed to accept touch inputs. In any position, user inputs may be communicated to an I/O subsystem or a processor of the portable information handling system 300 for processing, and then updated information may be communicated back via cable 352 to display 340 for displaying to the user. Hinge assembly 334 may be comprised of one or more discrete hinges or a unified assembly of hinges.

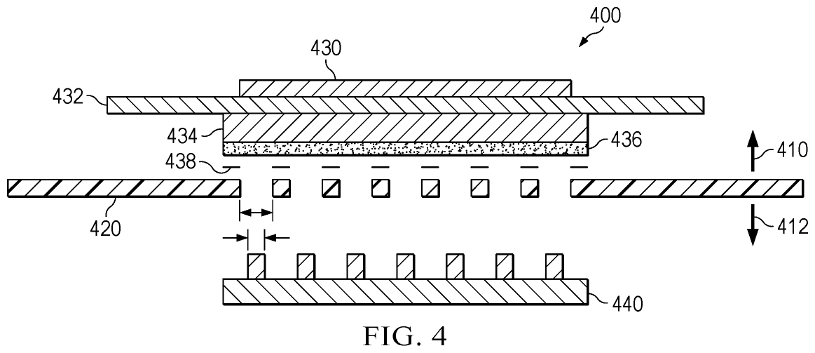

FIG. 4 shows a cross sectional block diagram of a thermal conduction cooling system 400. More specifically, the thermal conduction system 400 includes an information handling system thermal cooling device 410 and a docking station thermal cooling device 412. In certain embodiments, the information handling system thermal cooling device 410 is contained within a base chassis of a portable information handling system. In certain embodiments, the information handling system thermal cooling device 410 is positioned within a D-Cover 420 of the information handling system.

The information handling system thermal cooling device 410 interacts with the docking station thermal cooling device 412 to provide thermal conduction cooling via a mechanical and thermal interface between the information handling system thermal cooling device 410 and the docking station thermal cooling device 412. Such a thermal conduction cooling system 400 provides a user with more thermal headroom for their components when docked and a smaller more portable device when undocked without the risk of exposing the user to hot components. A thermal conduction cooling system 400 uses thermal conduction to draw heat from the portable information handling system.

In certain embodiments, the information handling system thermal cooling device 410 conducts heat from a heat source 430 away from the heat source. In certain embodiments, the information handling system thermal cooling device 410 includes one or more of a heat pipe solution 432, a heat spreader (e.g., a copper plate) 434, a thermal interface material (TIM) component 436 and a thermal interface material retention component 438. In certain embodiments, the docking station thermal cooling device 412 includes a docking station thermal component 440. In certain embodiments, one or more of the heat pipe solution 432, heat spreader 434 and thermal interface material component 436 are thermally coupled between the heat source 430 and the docking station thermal component 440 when the information handling system thermal cooling device 410 is mated with the docking station thermal cooling device 412. In certain embodiments, rather than a thermal interface material retention component, the TIM component 436 may be configured to include adhesive for thermally coupling the heat spread with the TIM component 436.

In various embodiments, the thermal conduction system 400 includes apertures in the bottom of the information handling system. In certain embodiments, the apertures are positioned below a CPU/GPU cold plate. In certain embodiments, some combination of a CPU, a GPU and the CPU/GPU cold plate corresponds to the heat source 430. In certain embodiments, the apertures are defined by the D-cover 420 of the portable information handling system. In certain embodiments, the apertures defined by the D-cover have a diameter between 0.95 mm-3.0 mm. In certain embodiments, the CPU/GPU cold plate includes a thin thermal pad on the bottom in the small hole area. In certain embodiments, the thermal pad corresponds to the TIM component 436. In certain embodiments, the thermal interface material retention component 438 includes apertures corresponding to the apertures in the bottom of the information handling system.

In certain embodiments, the docking station thermal component 440 includes thermally conductive pins which protrude from a surface of the docking station. In certain embodiments, the thermally conductive pins are formed from copper. When the information handling system is docked to the docking station, the thermally conductive pins mate with the apertures on the bottom of the portable information handling system and contact the thermal pad, thus providing a thermal conduction path from the thermal pad to the docking station. In certain embodiments, the plurality of thermal interface retention component apertures are aligned with the plurality of bottom cover portion apertures to allow the thermal interface material component to contact the plurality of thermally conductive pins of the docking station thermal component.

In certain embodiments, a diameter of the thermally conductive pins is slightly smaller (i.e., 5-20% smaller) than a diameter of the apertures. In certain embodiments, the thermally conductive pins have a height to bring the tops of the pins in contact with the thermal pad when the information handling system is attached to the docking station.

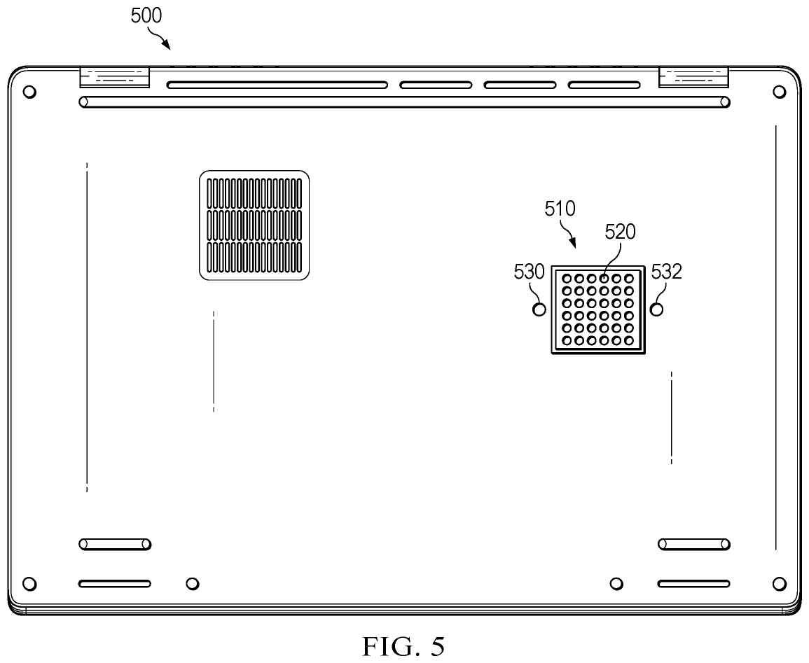

FIG. 5 shows a bottom view 500 of an information handling system with an information handling system thermal cooling device 510 of a thermal conduction cooling system. In certain embodiments, the information handling system thermal cooling portion 510 includes a plurality of housing apertures 520. In certain embodiments, the plurality of housing apertures are defined by a bottom cover portion of a main housing portion of the information handling system 500. In certain embodiments, the information handling system thermal cooling device 510 includes one or more alignment apertures 530, 532. In certain embodiments, the one or more alignment apertures 530, 532 are defined by the bottom cover portion of a main housing portion of the information handling system 500.

In certain embodiments, the plurality of housing apertures are contained within a rectangular shape. In certain embodiments, the plurality of housing apertures are contained within a square shape. In certain embodiments, the plurality of housing apertures are equally spaced. In certain embodiments, the plurality of housing apertures are arranged as a matrix having a rows and columns of housing apertures.

The plurality of thermal interface retention component apertures, the plurality of thermal interface retention component apertures being aligned with the plurality of bottom cover portion apertures to allow the thermal interface material component to contact a plurality of thermally conductive pins of a docking station thermal component

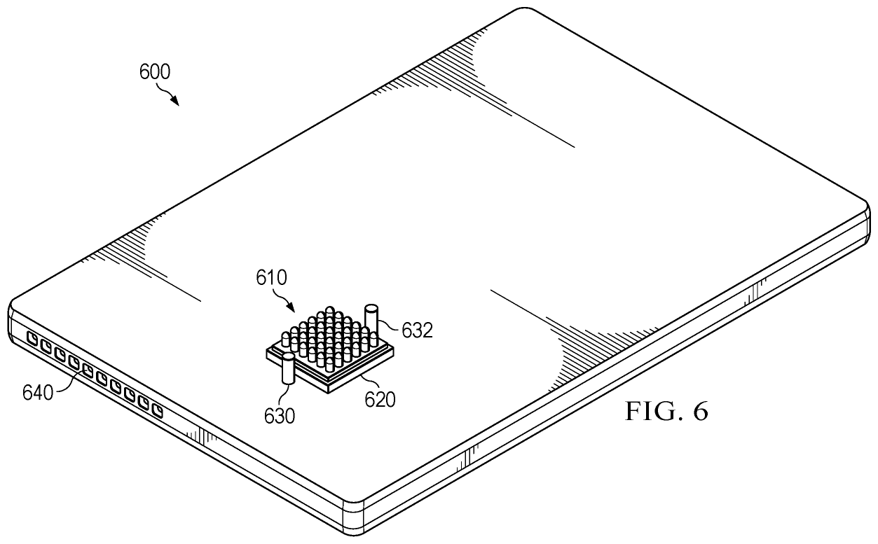

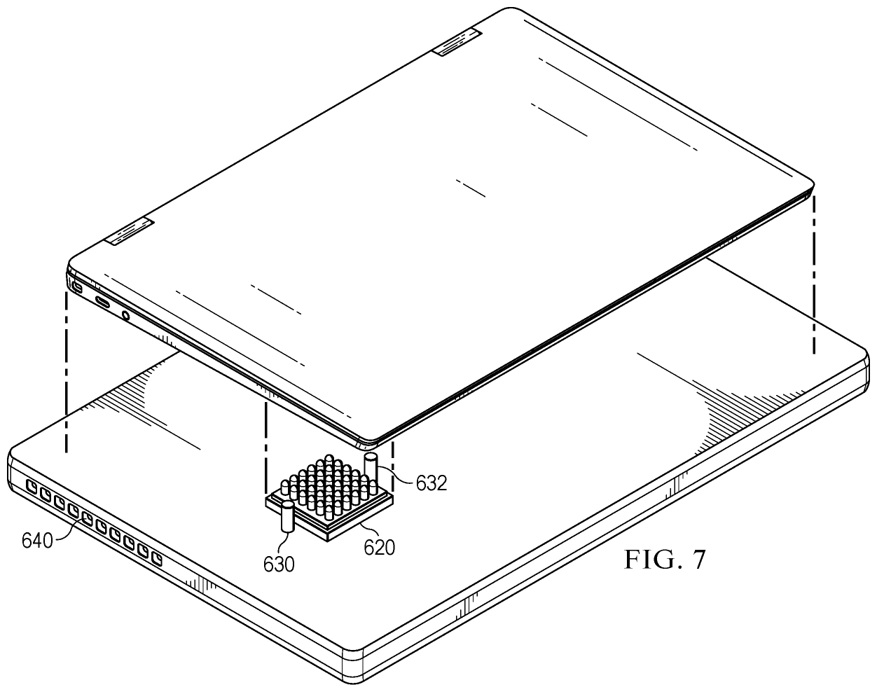

FIG. 6 shows a perspective view of a docking station 600 with a docking station thermal component 610. FIG. 7 shows a perspective view of an information handling system and docking solution with a thermal dock interface system.

In certain embodiments, the docking station thermal component 610 includes thermally conductive pins 620 which protrude from a surface of the docking station 600. In certain embodiments, the thermally conductive pins are formed from thermally conductive material such as copper. In certain embodiments, the docking station thermal component 610 includes one or more alignment pins 630, 632 which protrude from a surface of the docking station 600.

In certain embodiments, the plurality of thermally conductive pins are contained within a rectangular shape. In certain embodiments, the plurality of thermally conductive pins are contained within a square shape. In certain embodiments, the plurality of thermally conductive pins are equally spaced. In certain embodiments, the plurality of thermally conductive pins are arranged as a matrix having a rows and columns of thermally conductive pins.

In certain embodiments, the docking station 600 includes one or more airflow vents 640. In certain embodiments, the one or more airflow vents 640 enable heat emanating from the docking station thermal component 610 to exit the docking station. In certain embodiments, the one or more airflow vents 640 are thermally coupled to a fan contained within docking station 600 to promote airflow within the docking station 600. With such a thermal conduction system, thermal dock airflow and information handing system airflow paths are independent (i.e., not shared) so airflow within the thermal dock has a much lower flow impedance thus achieving a greater total (system+dock) airflow.

When the information handling system is docked to the docking station, the thermally conductive pins mate with the apertures on the bottom of the portable information handling system and contact the thermal pad, thus providing a thermal conduction path from the thermal pad to the docking station.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only and are not exhaustive of the scope of the invention.

Consequently, the invention is intended to be limited only by the spirit and scope of the appended claims, giving full cognizance to equivalents in all respects.

What is claimed is:

1. A main housing portion of a portable information handing system, comprising:
a top cover portion;
a bottom cover portion, the bottom cover portion defining a plurality of bottom cover portion apertures; and,
a thermal cooling device, the thermal cooling device comprising a thermal interface material component, the thermal interface material component being configured to contact a docking station thermal component of a docking station.

2. The main housing portion of claim 1, wherein the thermal cooling device further comprises:
a thermal interface material retention component, the thermal interface retention component defining a plurality of thermal interface retention component apertures, the plurality of thermal interface retention component apertures being aligned with the plurality of bottom cover portion apertures to allow the thermal interface material component to contact a plurality of thermally conductive pins of a docking station thermal component of a docking station.

3. The main housing portion of claim 1, wherein:
the bottom cover portion defines an alignment aperture; and,
the docking station thermal component includes an alignment pin, the alignment pin mating with the alignment aperture when the portable information handling system is attached to the docking station.

4. The main housing portion of claim 1, wherein:
the thermal cooling device includes a heat spreader thermally coupled between a heat source within the portable information handling system and the thermal interface material component.

5. The main housing portion of claim 4, wherein:
the thermal cooling device includes a heat pipe thermally coupled between the heat source within the portable information handling system and the heat spreader.

6. The main housing portion of claim 1, wherein:
the plurality of bottom cover portion apertures are arranged as a matrix.

7. The main housing portion of claim 1, wherein:
the docking station includes an airflow vent, the airflow vent enabling heat emanating from the docking station thermal component to exit the docking station.

8. An information handling system comprising:
a processor;
a data bus coupled to the processor; and
an information handling system chassis housing, the housing comprising
a base chassis, the base chassis housing the processor, the base chassis comprising
a top cover portion;
a bottom cover portion, the bottom cover portion defining a plurality of bottom cover portion apertures; and,
a thermal cooling device, the thermal cooling device comprising a thermal interface material component, the thermal interface material component being configured to contact a docking station thermal component of a docking station.

9. The information handling system of claim 8, wherein the thermal cooling device further comprises:
a thermal interface material retention component, the thermal interface retention component defining a plurality of thermal interface retention component apertures, the plurality of thermal interface retention component apertures being aligned with the plurality of bottom cover portion apertures to allow the thermal interface material component to contact a plurality of thermally conductive pins of a docking station thermal component of a docking station.

10. The information handling system of claim 8, wherein:
the bottom cover portion defines an alignment aperture; and,
the docking station thermal component includes an alignment pin, the alignment pin mating with the alignment aperture when the portable information handling system is attached to the docking station.

11. The information handling system of claim 8, wherein:
the thermal cooling device includes a heat spreader thermally coupled between a heat source within the portable information handling system and the thermal interface material component.

12. The information handling system of claim 10, wherein:
the thermal cooling device includes a heat pipe thermally coupled between the heat source within the portable information handling system and the heat spreader.

13. The information handling system of claim 8, wherein:
the plurality of bottom cover portion apertures are arranged as a matrix.

14. The information handling system of claim 8, wherein:
the docking station includes an airflow vent, the airflow vent enabling heat emanating from the docking station thermal component to exit the docking station.
